(19) United States
(12) Patent Application Publication
(10) Pub. No.: US 2025/0293639 A1
(43) Pub. Date: Sep. 18, 2025

(54) FREQUENCY CONVERTER

(71) Applicant: Fujitsu Limited, Kawasaki-shi (JP)

(72) Inventors: Jun KOBAYASHI, Tokorozawa (JP); Toshihiro SHIMURA, Yokohama (JP)

(73) Assignee: Fujitsu Limited, Kawasaki-shi (JP)

(21) Appl. No.: 19/044,735

(22) Filed: Feb. 4, 2025

(30) Foreign Application Priority Data
Mar. 12, 2024 (JP) 2024-38015

(51) Int. Cl. H03D 7/14; H03G 3/30

(52) U.S. Cl. CPC H03D 7/1441; H03D 7/1458; H03G 3/3042; H03G 2201/307

(57) ABSTRACT

A frequency converter includes a transistor configured to configure a double balanced mixer, a load circuit provided to a drain side of the transistor, a first terminal coupled to the load circuit, an impedance circuit provided to a source side of the transistor, a second terminal coupled to a source of the transistor, a drive circuit configured to provide a local oscillator signal to a gate of the transistor, and a current control circuit configured to control a current that flows from the load circuit toward the impedance circuit via the transistor or a current that flows from the impedance circuit toward the load circuit via the transistor.

### CROSS-REFERENCE TO RELATED APPLICATION

This application claims foreign priority to Japanese Patent Application No. 2024-38015, filed on Mar. 12, 2024, the entire contents of which are incorporated herein by reference.

### FIELD

The embodiments discussed herein are related to a frequency converter used in wireless communication.

### BACKGROUND

In many cases, a base station for wireless communication has a function for up-converting a transmission signal in a baseband domain or an intermediate frequency domain into a radio frequency domain and a function for down-converting a reception signal in the radio frequency domain into the baseband domain or the intermediate frequency domain. For example, the base station includes a frequency converter.

In fifth generation mobile communication (5G new radio (NR)) or post 5G communication, utilization of a millimeter waveband frequency has been studied in order to cope with ultra-high speed communication, ultra-low delay, and multiple simultaneous connections. For example, In addition to the 28 GHz and 39 GHz bands, the International Telecommunication Union (ITU) has allocated the 45.5-48.2 GHz and 66-71 GHz frequency bands for 5G wireless communication. Then, Millimeter waves enable high-gain directional antennas of compact size. Therefore, it is possible to provide a high throughput.

However, the high directivity of millimeter wave bands necessitates the deployment of numerous base stations to expand coverage. Then, in order to deploy a large number of base stations while suppressing cost of an entire wireless communication system, power saving and miniaturization of the base station (for example, radio unit (RU) are required.

Note that a bidirectional variable gain amplifier for a radio frequency communication system has been proposed. Furthermore, a receiver circuit that receives a radio frequency signal has been proposed. Moreover, a bidirectional frequency converter that converts a frequency of a signal, used for a wireless unit circuit of a wireless communication device for mobile communication or the like has been proposed.

Japanese Laid-open Patent Publication No. 2022-138125, Japanese Laid-open Patent Publication No. 2023-544445, and Japanese Patent No. 4881596 are disclosed as related arts.

### SUMMARY

According to an aspect of the embodiments, a frequency converter includes a transistor configured to configure a double balanced mixer, a load circuit provided to a drain side of the transistor, a first terminal coupled to the load circuit, an impedance circuit provided to a source side of the transistor, a second terminal coupled to a source of the transistor, a drive circuit configured to provide a local oscillator signal to a gate of the transistor, and a current control circuit configured to control a current that flows from the load circuit toward the impedance circuit via the transistor or a current that flows from the impedance circuit toward the load circuit via the transistor.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating an example of a frequency converter;

FIG. 2 is a diagram illustrating another example of the frequency converter;

FIG. 3 is a diagram illustrating an example of a frequency converter according to a first embodiment;

FIGS. 4A and 4B are diagrams for explaining an operation of the frequency converter;

FIGS. 5A and 5B are diagrams (part 1) for explaining an effect according to the embodiment;

FIGS. 6A and 6B are diagrams (part 2) for explaining the effect according to the embodiment;

FIG. 7 is a diagram illustrating an example of a frequency converter according to a second embodiment;

FIG. 8 is a diagram for explaining LO leak power leaking from an RF terminal;

FIG. 9 is a diagram for explaining a method for suppressing the LO leak power;

FIG. 10 is a diagram illustrating an example of a frequency converter according to a first variation;

FIG. 11 is a diagram illustrating an example of a frequency converter according to a second variation;

FIG. 12 is a diagram illustrating an example of a frequency converter according to a third variation;

FIG. 13 is a diagram illustrating an example of a frequency converter according to fourth variation;

FIG. 14 is a diagram illustrating an example of a frequency converter according to a fifth variation;

FIG. 15 is a diagram illustrating an example of a frequency converter according to a sixth variation;

FIG. 16 is a diagram illustrating an example of a frequency converter according to a seventh variation; and

FIG. 17 is a diagram illustrating an example of a communication device using the frequency converter.

### DESCRIPTION OF EMBODIMENTS

A radio frequency circuit of a wireless communication system (for example, base station application) includes a transmission system and a reception system. For example, the wireless communication system has a frequency conversion function for up-converting a transmission signal and a frequency conversion function for down-converting a reception signal. Furthermore, by partially sharing the transmission system and the reception system, simplification, miniaturization, or cost reduction of the wireless system has been attempted. In this case, the wireless communication system includes a bidirectional frequency converter. However, in related art, power consumption of a communication device including the bidirectional frequency converter (here, wireless communication system) is large.

An object of one aspect of the embodiment is to reduce power consumption of a communication system including a frequency converter that performs frequency conversion for up-converting a transmission signal and performs frequency conversion for down-converting a reception signal.

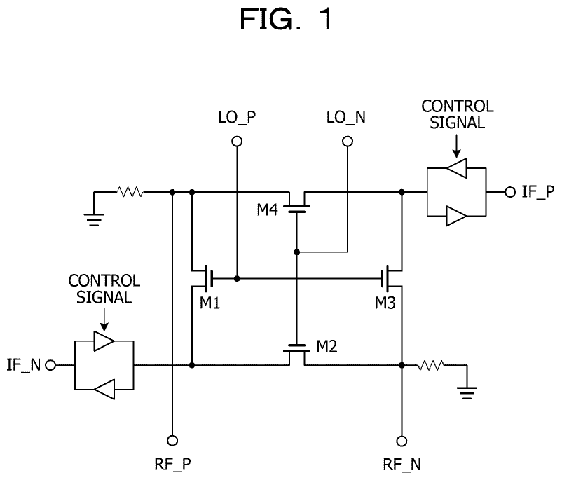

FIG. 1 illustrates an example of a frequency converter. The frequency converter illustrated in FIG. 1 has a function for converting an intermediate frequency signal into a radio frequency signal and a function for converting the radio frequency signal into the intermediate frequency signal. Although an intermediate frequency is not particularly limited, the intermediate frequency indicates one to 10 GHz herein. Although a radio frequency is not particularly limited, the radio frequency indicates a frequency higher than 10 GHz herein.

Note that, in the following description, the intermediate frequency signal may be referred to as an “intermediate frequency (IF) signal”. The radio frequency signal may be referred to as a “radio frequency (RF) signal”. A local oscillator signal used for frequency conversion may be referred to as a “local oscillator (LO) signal”. When a differential signal is processed by the frequency converter, a pair of signals configuring the differential signal may be identified as “positive (P)” and “negative (N)”.

In up-converting phase, an IF signal (IF_P) is provided to transistors M3 and M4 via a direction controller, and an IF signal (IF_N) is provided to transistors M1 and M2 via the direction controller. Furthermore, an LO signal (LO_P) is provided to gates of the transistors M1 and M3, and an LO signal (LO_N) is provided to gates of the transistors M2 and M4. Then, an RF signal (RF_P) is output via a terminal coupled to the transistors M1 and M4, and an RF signal (RF_N) is output via a terminal coupled to the transistors M2 and M3.

In down-converting phase, the RF signal (RF_P) is provided to the transistors M1 and M4, and the RF signal (RF_N) is provided to the transistors M2 and M3. Furthermore, an LO signal (LO_P) is provided to the gates of the transistors M1 and M3, and an LO signal (LO_N) is provided to the gates of the transistors M2 and M4. Then, the IF signal (IF_P) is output from the transistors M3 and M4 via the direction controller, and the IF signal (IF_N) is output from the transistors M1 and M2 via the direction controller.

In this way, in the frequency converter illustrated in FIG. 1, each of the transistors M1 to M4 is driven by the signal in a state where no direct current is supplied. For example, this frequency converter operates as a passive type mixer. Therefore, a configuration illustrated in FIG. 1 has a large conversion loss. Furthermore, in order to generate the RF signal having a predetermined output level (for example, transmission power for base station to achieve predetermined communication coverage), it is necessary to increase power of the LO signal. It is necessary to increase a gain of an amplifier that amplifies the signals (RF, IF, and LO) input into the frequency converter and/or the signals (RF and IF) output from the frequency converter. Therefore, power consumption of a communication device including the frequency converter increases.

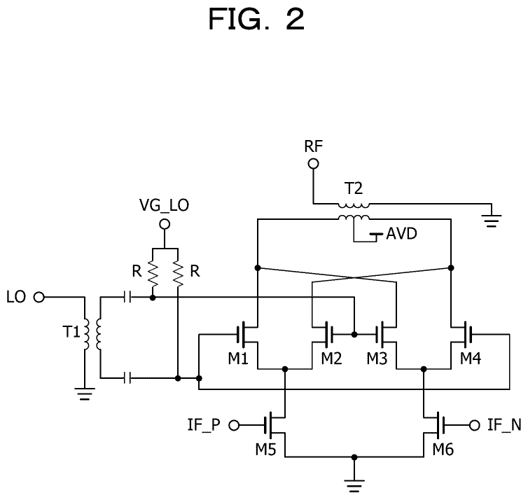

FIG. 2 illustrates another example of the frequency converter. The frequency converter illustrated in FIG. 2 is a double balanced mixer (DBM) frequency converter including a DBM. The double balanced mixer includes the four transistors M1 to M4. Note that this frequency converter converts an IF signal into an RF signal.

The double balanced mixer includes two transistor pairs. One of the transistor pairs includes the transistors M1 and M2. The transistors M1 and M2 are coupled to each other in parallel. Another one of the transistor pairs includes the transistors M3 and M4. The transistors M3 and M4 are coupled to each other in parallel. Sources of the transistors M1 and M2 are coupled to a drain of a transistor M5. Sources of the transistors M3 and M4 are coupled to a drain of a transistor M6. Sources of the transistors M5 and M6 are coupled to ground.

Gates of the transistors M2 and M3 are coupled to one terminal of secondary winding of a transformer T1, and gates of the transistors M1 and M4 are coupled to another terminal of the secondary winding of the transformer T1. One terminal of primary winding of the transformer T1 is used to input the LO signal. Another terminal of the primary winding of the transformer T1 is coupled to the ground. Note that a capacitor used to cut a direct current (DC) component may be included between the transformer T1 and the double balanced mixer. Furthermore, a bias voltage is applied to the gate of each of the transistors M1 to M4, by a power supply VG_LO and a resistor R. This bias voltage is set so that each of the transistors M1 to M4 operates in a saturation region.

Drains of the transistors M1 and M3 are coupled to one terminal of primary winding of a transformer T2, and drains of the transistors M2 and M4 are coupled to another terminal of the primary winding of the transformer T2. A midpoint of the primary winding of the transformer T2 (for example, center tap) is coupled to a power supply AVD. The power supply AVD generates a predetermined DC voltage. One terminal of secondary winding of the transformer T2 is used to output the RF signal, and another terminal of the secondary winding of the transformer T2 is coupled to the ground.

In the frequency converter having the above configuration, the IF signal is provided to the transistors M5 and M6. Here, the IF signal is a differential signal and includes the signal IF_P and the signal IF_N. The signal IF_P is provided to a gate of the transistor M5, and the signal IF_N is provided to a gate of the transistor M6. Furthermore, the LO signal is provided to the double balanced mixer via the transformer T1. For example, the LO signal is provided to the gate of each of the transistors M1 to M4.

Then, the RF signal is output via an RF terminal coupled to the transformer T2. The RF signal includes a component of an input signal (for example, IF signal). Furthermore, a frequency of the RF signal substantially corresponds to a sum of a frequency of the IF signal and a frequency of the LO signal. For example, an input IF signal is converted into the RF signal and is output.

In the frequency converter illustrated in FIG. 2, at the time of operation, a direct current flows from the power supply AVD to the ground via the transistors M1 to M6. For example, the transistors M1 to M4 configuring the double balanced mixer are held in an active state, and the frequency converter operates as an active type mixer. Therefore, as compared with the configuration illustrated in FIG. 1, a conversion loss of the frequency converter illustrated in FIG. 2 is smaller. However, the frequency converter illustrated in FIG. 2 is a single-direction converter.

Furthermore, in a case where the transformer T2 is an ideal transformer and characteristics of the transistors M1 to M4 configuring the double balanced mixer are uniform, power of an LO signal component output from the RF terminal becomes zero. However, typically, the characteristics of the transistors M1 to M4 vary. Therefore, not only the RF signal but also the LO signal component is output via the RF terminal. For example, the power of the LO signal component may be generated as a spurious. Note that, in a new radio frequency band (frequency range 2: FR2) of 5G, the spurious is required to be equal to or less than-13 dBm.

### First Embodiment

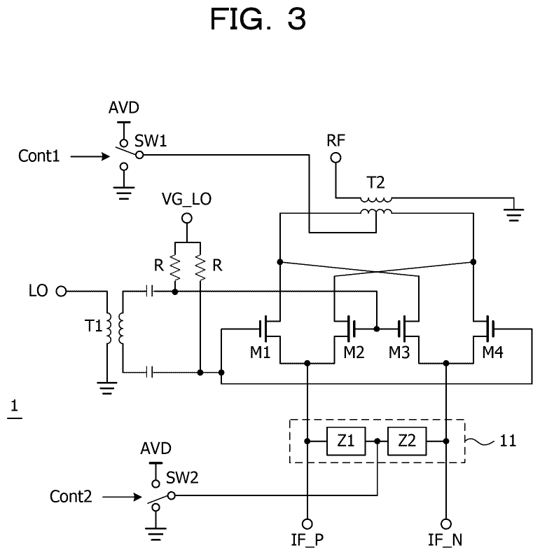

FIG. 3 illustrates an example of a frequency converter according to a first embodiment. A frequency converter 1 according to the first embodiment includes transistors M1 to M4 configuring a double balanced mixer and transformers T1 and T2, similarly to the frequency converter illustrated in FIG. 2. Furthermore, the frequency converter 1 includes an RF terminal, an LO terminal, and IF (IF_P and IF_N) terminals.

The LO terminal is electrically coupled to primary winding of the transformer T1, similarly to the frequency converter illustrated in FIG. 2. For example, an LO signal is input into the double balanced mixer via the transformer T1. Here, one terminal of secondary winding of the transformer T1 is coupled to gates of the transistors M2 and M3, and another terminal of the secondary winding of the transformer T1 is coupled to gates of the transistors M1 and M4. Therefore, for example, when the transistors M2 and M3 are driven by the LO signal, the transistors M1 and M4 are driven by an LO signal of which a phase is inverted.

The RF terminal is electrically coupled to secondary winding of the transformer T2. Primary winding of the transformer T2 is electrically coupled to a drain side of the double balanced mixer, similarly to the frequency converter illustrated in FIG. 2. However, in the frequency converter 1, a midpoint of the primary winding of the transformer T2 is electrically coupled to a switch SW1.

Note that the transformer T2 transmits a signal from the double balanced mixer to the RF terminal at the time of transmission of a radio signal and transmits a signal from the RF terminal to the double balanced mixer at the time of reception of the radio signal. For example, the transformer T2 may bidirectionally transmit the signals. However, in the following description, for convenience, one winding of the transformer T2 (winding coupled to transistors M1 to M4 in FIG. 3) may be referred to as “primary winding”, and another winding (winding coupled to RF terminal in FIG. 3) may be referred to as “secondary winding”.

The IF terminal is electrically coupled to a source side of the double balanced mixer. For example, the IF_P terminal is electrically coupled to sources of the transistors M1 and M2, and the IF_N terminal is electrically coupled to sources of the transistors M3 and M4. Furthermore, the frequency converter 1 includes an impedance circuit 11, on the source side of the double balanced mixer. The impedance circuit 11 includes impedance circuits Z1 and Z2.

The impedance circuit Z1 is provided between a switch SW2 and the IF_P terminal. For example, the impedance circuit Z1 is provided between the switch SW2 and the sources of the transistors M1 and M2. Similarly, the impedance circuit Z2 is provided between the switch SW2 and the IF_N terminal. For example, the impedance circuit Z2 is provided between the switch SW2 and the sources of the transistors M3 and M4.

The impedance circuit 11 (Z1 and Z2) has a small resistance value in a DC region and a high impedance in an intermediate frequency domain. Therefore, although not particularly limited, each of the impedance circuits Z1 and Z2 is configured, for example, by coupling a resistance element and an inductance element in series. Alternatively, each of the impedance circuits Z1 and Z2 may be realized by a resonance circuit.

The switch SW1 includes two input terminals and one output terminal. One input terminal is coupled to a power supply AVD, and another input terminal is coupled to ground. The output terminal is electrically coupled to the midpoint of the primary winding of the transformer T2. Then, the switch SW1 couples the midpoint of the primary winding of the transformer T2 to the power supply AVD or the ground, according to a control signal Cont1.

The switch SW2 includes two input terminals and one output terminal. One input terminal is coupled to the power supply AVD, and another input terminal is coupled to the ground. The output terminal is electrically coupled to the impedance circuit 11. For example, the output terminal of the switch SW2 is coupled to the sources of the transistors M1 and M2 via the impedance circuit Z1 and is coupled to the sources of the transistors M3 and M4 via the impedance circuit Z2. Then, the switch SW2 couples the impedance circuit 11 to the power supply AVD or the ground, according to a control signal Cont2.

In this way, the switch SW2 couples the impedance circuit 11 (Z1 and Z2) to the power supply AVD or the ground. Therefore, the resistance value of each of the impedance circuits Z1 and Z2 is determined so that source potentials of the transistors M1 to M4 are set to appropriate values. Furthermore, since each of the impedance circuits Z1 and Z2 has a high impedance in the intermediate frequency domain, an IF signal component is less likely to reach the power supply AVD.

The control signal (Cont1 and Cont2) instructs an operation mode of the frequency converter 1, by controlling a direction of a direct current flowing in the frequency converter 1. For example, the control signal (Cont1 and Cont2) instructs whether the frequency converter 1 operates in a transmission mode or a reception mode. Furthermore, the control signal Cont1 and the control signal Cont2 are synchronized with each other. For example, when the frequency converter 1 operates in the transmission mode, the control signal Cont1 controls the switch SW1 so that the midpoint of the primary winding of the transformer T2 is coupled to the power supply AVD, and the control signal Cont2 controls the switch SW2 so that the impedance circuit 11 is coupled to the ground. When the frequency converter 1 operates in the reception mode, the control signal Cont1 controls the switch SW1 so that the midpoint of the primary winding of the transformer T2 is coupled to the ground, and the control signal Cont2 controls the switch SW2 so that the impedance circuit 11 is coupled to the power supply AVD.

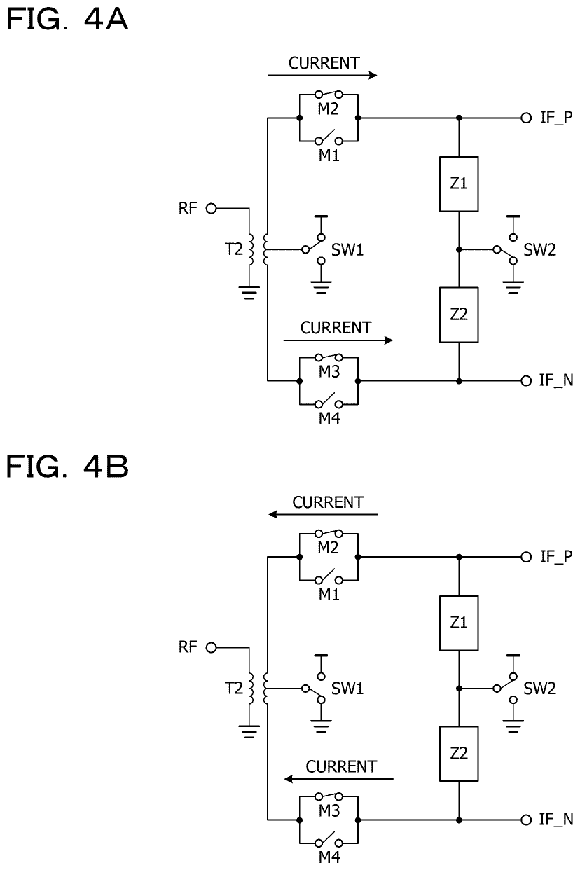

FIGS. 4A and 4B are diagrams for explaining an operation of the frequency converter 1. Note that, in FIGS. 4A and 4B, for easy understanding of the drawings, wiring between the transformer T2 and the transistors M1 to M4 is schematically illustrated. For example, the transformer T2 and the transistors M1 to M4 are actually coupled as illustrated in FIG. 3.

The LO signal is provided to the transistors M1 to M4 configuring the double balanced mixer, via the transformer T1 illustrated in FIG. 3. In this embodiment, the LO signal is a differential signal including a signal LO_P and a signal LO_N. Then, for example, the signal LO_P is provided to the gates of the transistors M2 and M3, and the signal LO_N is provided to the gates of the transistors M1 and M4. For example, the transistors M2 and M3 are driven by the same signal (for example, LO_P), and in addition, the transistors M1 and M4 are driven by the same signal (for example, LO_N).

When the frequency converter 1 operates in the transmission mode, as illustrated in FIG. 4A, the switch SW1 is controlled by the control signal Cont1, and the midpoint of the primary winding of the transformer T2 is coupled to the power supply AVD. Furthermore, the switch SW2 is controlled by the control signal Cont2, and the impedance circuit 11 (Z1 and Z2) is coupled to the ground. Then, the IF signal (IF_P and IF_N) is input via the IF terminal.

In this case, a current flows from the power supply AVD toward the ground via the transformer T2, the transistors M1 to M4, and the impedance circuit 11 (Z1 and Z2). Here, a bias voltage is applied to the transistors M1 to M4 so as to operate in a saturation region. In the example illustrated in FIG. 3, the bias voltage is generated by a power supply VG_LO and a resistor R. Therefore, the transistors M1 to M4 operate as active type circuits.

The transistors M1 to M4 are driven by the LO signal. Therefore, the signal IF_P is multiplied by the LO signal, in the transistors M1 and M2. Furthermore, the signal IF_N is multiplied by the LO signal, in the transistors M3 and M4. For example, the LO signal is multiplied to the input IF signal. Therefore, the IF signal is up-converted by the LO signal. Then, a signal (for example, RF signal) generated by the up-conversion is output via the RF terminal.

When the frequency converter 1 operates in the reception mode, as illustrated in FIG. 4B, the switch SW1 is controlled by the control signal Cont1, and the midpoint of the primary winding of the transformer T2 is coupled to the ground. Furthermore, the switch SW2 is controlled by the control signal Cont2, and the impedance circuit 11 (Z1 and Z2) is coupled to the power supply AVD. Then, the RF signal is input via the RF terminal.

In this case, the current flows from the power supply AVD toward the ground via the impedance circuit 11 (Z1 and Z2), the transistors M1 to M4, and the transformer T2. Therefore, the transistors M1 to M4 operate as the active type circuits, similarly to the time when the frequency converter 1 operates in the transmission mode.

The transistors M1 to M4 are driven by the LO signal. Therefore, the RF signal is multiplied by the LO signal, in the transistors M1 and M2. Furthermore, the RF signal is multiplied by the LO signal, in the transistors M3 and M4. Therefore, the RF signal is down-converted by the LO signal. Then, a signal (for example, IF signal) generated by the down-conversion is output via the IF terminal.

In this way, the frequency converter 1 realizes bidirectional frequency conversion, by switching the direction of the direct current flowing in the frequency converter 1. For example, by forming a state where the direct current flows from the RF terminal side to the IF terminal side, conversion from the IF signal into the RF signal is realized. Furthermore, by forming a state where the direct current flows from the IF terminal side to the RF terminal side, conversion from the RF signal into the IF signal is realized. At this time, since the transistors M1 to M4 configuring the double balanced mixer operate as the active type circuits, a conversion loss is small. Alternatively, an RF signal having a predetermined output level (for example, transmission power for base station to achieve predetermined communication coverage) can be generated, without increasing power of the LO signal. Therefore, according to the configuration illustrated in FIG. 3, power consumption of a communication device including the frequency converter can be reduced.

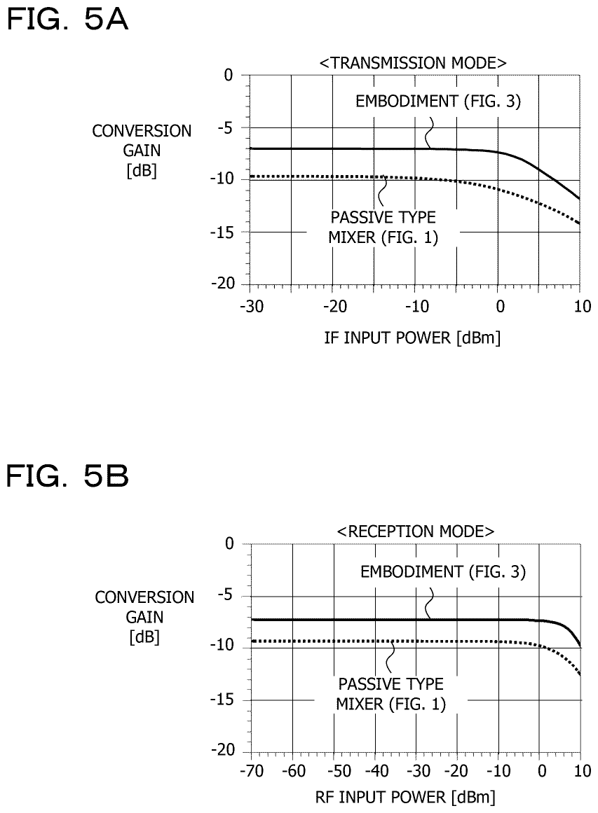

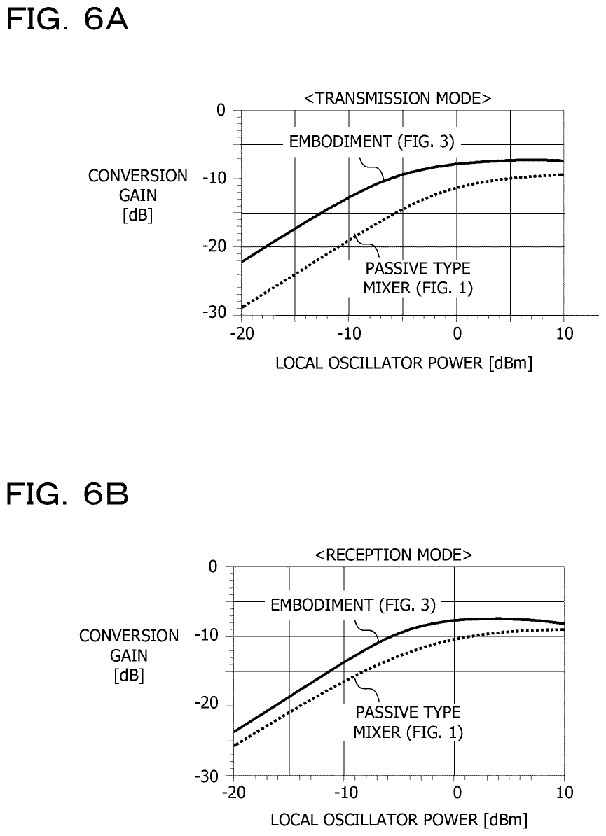

FIGS. 5A to 6B are diagrams for explaining an effect according to the embodiment. Here, the passive type mixer illustrated in FIG. 1 and the embodiment illustrated in FIG. 3 are compared. Note that, in FIGS. 5A to 6B, results of simulations performed under the following conditions are illustrated. frequency of IF signal: 7 GHZ, frequency of LO signal: 40 GHZ, frequency of RF signal: 47 GHz

FIG. 5A illustrates a conversion gain in the transmission mode. In the transmission mode, the frequency converter up-converts the IF signal using the LO signal and outputs the RF signal. Therefore, the conversion gain in the transmission mode indicates a ratio of output power of the RF signal to input power of the IF signal.

According to this simulation, as compared with the passive type mixer illustrated in FIG. 1, the conversion gain in the transmission mode is improved by about three dB. Therefore, in a case where an RF signal with predetermined power is output, in a communication device using the frequency converter 1 according to the embodiment can reduce a power gain of an amplifier that amplifies the RF signal. Therefore, for example, power consumption of the amplifier that amplifies the RF signal can be reduced.

FIG. 5B illustrates a conversion gain in the reception mode. In the reception mode, the frequency converter down-converts the RF signal using the LO signal and outputs the IF signal. Therefore, the conversion gain in the reception mode indicates a ratio of output power of the IF signal to reception power of the RF signal.

According to this simulation, as compared with the passive type mixer illustrated in FIG. 1, the conversion gain in the reception mode is improved by about two dB. Therefore, in this case, power consumption of an amplifier that amplifies the IF signal can be reduced.

FIG. 6A illustrates a relationship between power of the LO signal and the conversion gain in the transmission mode. Furthermore, FIG. 6B illustrates a relationship between the power of the LO signal and the conversion gain in the reception mode. For example, this simulation indicates power of the LO signal required to obtain a predetermined conversion gain.

According to this simulation, as compared with the passive type mixer illustrated in FIG. 1, the power of the LO signal required to obtain the predetermined conversion gain decreases. For example, it is assumed that a required value of the conversion gain in the transmission mode be −10 dB. In this case, the passive type mixer illustrated in FIG. 1 needs to generate an LO signal of two dBm. On the other hand, it is sufficient for the frequency converter 1 according to the embodiment to generate an LO signal of −six dBm. Therefore, according to the configuration according to the embodiment, the power consumption of the communication device (for example, power consumption of amplifier that amplifies LO signal) can be reduced. Note that the power of the LO signal generated in the communication device is equal to or less than zero dBm, in many cases.

In the frequency converter 1 illustrated in FIG. 3, the transformer T2 is an example of a load circuit provided to a drain side of the transistors M1 to M4. The transformer T1 is an example of a drive circuit that provides the LO signal to the gates of the transistors M1 to M4. The switch SW1 and the switch SW2 are examples of a current control circuit that controls a current flowing from the load circuit to the impedance circuit via the transistor or a current flowing from the impedance circuit to the load circuit via the transistor.

### Second Embodiment

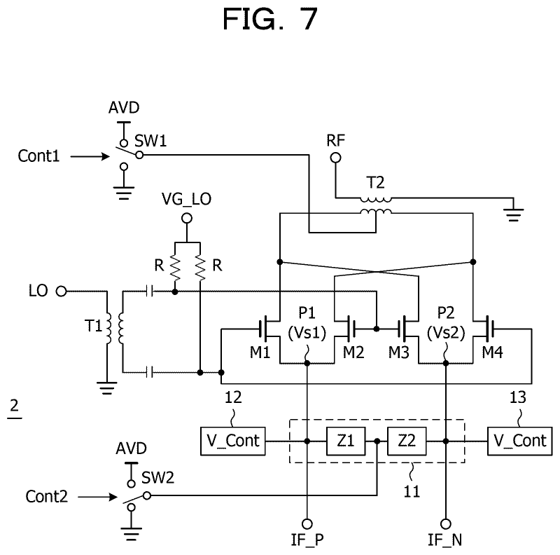

FIG. 7 illustrates an example of a frequency converter according to a second embodiment. A configuration of a frequency converter 2 according to the second embodiment is substantially the same as the frequency converter 1 according to the first embodiment illustrated in FIG. 3. However, the frequency converter 2 includes voltage control circuits 12 and 13, in addition to the configuration illustrated in FIG. 3.

Each of the voltage control circuits 12 and 13 includes a digital/analog converter (DAC). A voltage instruction is provided to the DAC. The voltage instruction is, for example, digital data indicating a voltage value. Furthermore, the voltage instruction is generated, for example, by a microcomputer (not illustrated). Alternatively, a manufacturer or a user of the frequency converter 2 may use a computer and generate the voltage instruction. Then, the DAC outputs a DC voltage indicated by the voltage instruction, by converting the voltage instruction into an analog signal. For example, each of the voltage control circuits 12 and 13 can output the DC voltage indicated by the voltage instruction. Note that a configuration including the DAC is an example, and the voltage control circuits 12 and 13 may be realized by a configuration that does not include the DAC.

The DC voltage output from the voltage control circuit 12 is applied to sources of transistors M1 and M2. For example, the voltage control circuit 12 controls potentials of the sources of the transistors M1 and M2. Note that, in the following description, the sources of the transistors M1 and M2 may be referred to as a “point P1”. Furthermore, the potentials of the sources of the transistors M1 and M2 may be referred to as “Vs1”.

Similarly, the DC voltage output from the voltage control circuit 13 is applied to sources of transistors M3 and M4. For example, the voltage control circuit 13 controls potentials of the sources of the transistors M3 and M4. Note that, in the following description, the sources of the transistors M3 and M4 may be referred to as a “point P2”. Furthermore, the potentials of the sources of the transistors M3 and M4 may be referred to as “Vs2”.

The voltage control circuits 12 and 13 control the DC voltage to be applied to the point P1 and the point P2, so that LO leak power leaking from an RF terminal decreases. For example, the voltage control circuits 12 and 13 control potentials of the point P1 and the point P2 so that the LO leak power leaking from the RF terminal decreases. Therefore, first, the LO leak power leaking from the RF terminal will be described. Note that the LO leak power represents power of an LO signal component appearing in the RF terminal via a transformer T2.

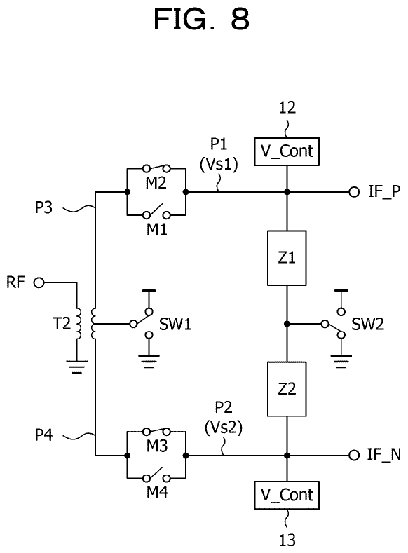

FIG. 8 is a diagram for explaining the LO leak power leaking from the RF terminal. Note that, in FIG. 8, drains of the transistors M1 and M2 may be referred to as a “point P3”, and drains of the transistors M3 and M4 may be referred to as a “point P4”. Furthermore, in FIG. 8, for easy understanding of the drawings, wiring between the transformer T2 and the transistors M1 to M4 is schematically illustrated. For example, the transformer T2 and the transistors M1 to M4 are actually coupled as illustrated in FIG. 7.

In FIGS. 7 and 8, the LO leak power leaking from the RF terminal is determined based on an amplitude and a phase of an LO signal at the point P3 and an amplitude and a phase of an LO signal at the point P4. For example, when it is assumed that the transformer T2 be an ideal transformer, if the amplitudes of the LO signals at the point P3 and the point P4 are the same as each other and the phases of the LO signals at the point P3 and the point P4 are the same as each other, power of the LO signal output via the RF terminal (for example, LO leak power) is zero.

Here, the amplitude and the phase of the LO signal at the point P3 may be adjusted by controlling the potential Vs1 at the point P1. Furthermore, the amplitude of the phase of the LO signal at the point P4 may be adjusted by controlling the potential Vs2 at the point P2. Therefore, if the potential Vs1 and the potential Vs2 are controlled so that the amplitudes of the LO signals at the point P3 and the point P4 are the same as each other and the phases of the LO signals at the point P3 and the point P4 are the same as each other, the LO leak power becomes zero.

However, in a procedure for reducing the LO leak power, it is not necessary to necessarily control both of the potential Vs1 and the potential Vs2. For example, in a state where one of the potential Vs1 and the potential Vs2 is fixed to a predetermined value, by controlling the another potential, the LO leak power can be reduced.

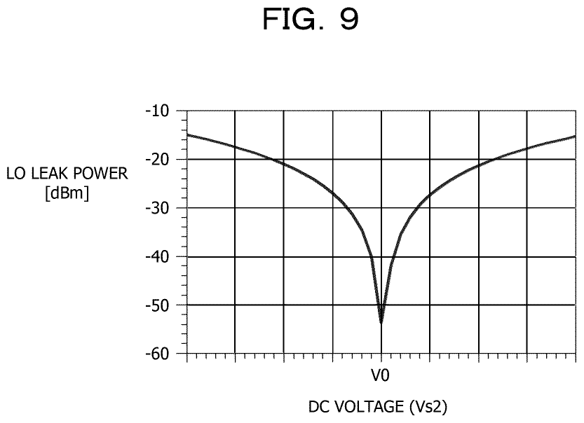

FIG. 9 is a diagram for explaining a method for suppressing the LO leak power. In this embodiment, one of the potential Vs1 and the potential Vs2 is fixed to the predetermined value. As an example, it is assumed that the potential Vs1 be fixed to the predetermined value. In this case, the horizontal axis of the graph illustrated in FIG. 9 represents the potential Vs2.

In the procedure for reducing the LO leak power, in this embodiment, the potential Vs1 is fixed to the predetermined value. For example, the voltage control circuit 12 outputs a predetermined fixed value (for example, zero). Alternatively, the frequency converter 2 does not need to include the voltage control circuit 12.

Subsequently, an output voltage of the voltage control circuit 13 is swept. Here, it is assumed that a microcomputer (not illustrated) generate the voltage instruction. In this case, this microcomputer changes a value indicated by the voltage instruction at predetermined intervals (for example, one mV). As a result, the potential Vs2 at the point P2 illustrated in FIG. 7 or 8 gradually changes. Then, the LO leak power appearing in the RF terminal changes as illustrated in FIG. 9. At this time, the LO leak power has a local minimum point. In the example illustrated in FIG. 9, when the potential Vs2 is V0, the LO leak power is minimized. Therefore, in this case, the microcomputer maintains the voltage instruction for setting the potential Vs2 to be V0. As a result, the LO leak power output via the RF terminal decreases.

Note that characteristics of the transistors M1 to M4 may depend on a temperature. Furthermore, the characteristics of the transistors M1 to M4 may change with the lapse of time. Therefore, the voltage instruction provided to the voltage control circuits 12 and 13 may be feedback-controlled while monitoring the LO leak power.

In this way, in the second embodiment, the LO leak power output via the RF terminal is suppressed. For example, a spurious is suppressed, and quality of wireless communication is improved. Note that the spurious can be suppressed by providing a filter that removes a frequency component of the LO signal. However, in this case, since power of an RF signal is lowered by the filter, power consumption of an amplifier that amplifies the RF signal increases. Therefore, the second embodiment contributes to reduction in the power consumption. In addition, in the configuration in which the spurious is removed using the filter, the number of components increases, which is disadvantageous in miniaturization of the communication device.

### <Variations>

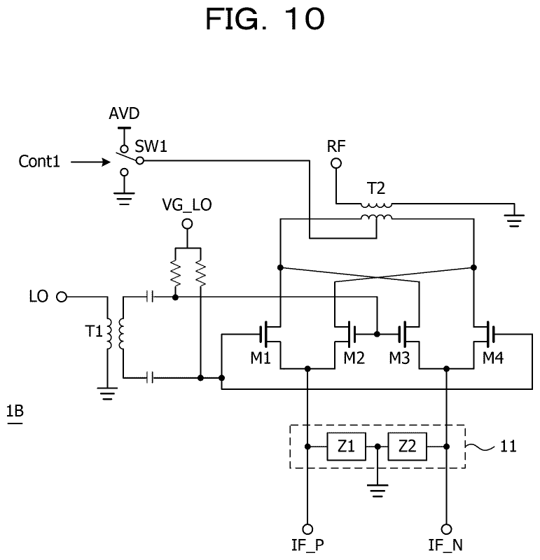

FIG. 10 illustrates an example of a frequency converter according to a first variation. A frequency converter 1B according to the first variation includes the double balanced mixer (for example, transistors M1 to M4), the transformers T1 and T2, the impedance circuit 11, and the switch SW1, similarly to the frequency converter 1 illustrated in FIG. 3. However, the frequency converter 1B does not include the switch SW2 illustrated in FIG. 3, and the impedance circuit 11 is coupled to the ground. For example, the sources of the transistors M1 and M2 are coupled to the ground via the impedance circuit Z1, and the sources of the transistors M3 and M4 are coupled to the ground via the impedance circuit Z2. Note that, in the frequency converter 1B, the current control circuit that controls the direct current flowing via the transistors M1 to M4 is realized by the switch SW1.

When the frequency converter 1B operates in the transmission mode, the switch SW1 couples the midpoint of the primary winding of the transformer T2 to the power supply AVD. In this case, the current flows from the power supply AVD toward the ground via the transformer T2, the transistors M1 to M4, and the impedance circuit 11 (Z1 and Z2). For example, the transistors M1 to M4 are held in the active state. Therefore, the frequency converter 1B operates as an active-type frequency converter in the transmission mode in which the IF signal is converted into the RF signal and output.

When the frequency converter 1B operates in the reception mode, the switch SW1 couples the midpoint of the primary winding of the transformer T2 to the ground. In this case, the direct current does not substantially flow via the transistors M1 to M4. For example, the double balanced mixer operates as a passive-type circuit.

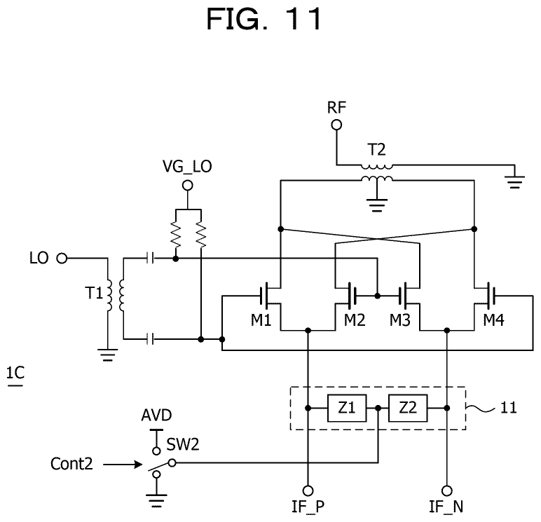

FIG. 11 illustrates an example of a frequency converter according to a second variation. A frequency converter 1C according to the second variation includes the double balanced mixer (for example, transistors M1 to M4), the transformers T1 and T2, the impedance circuit 11, and the switch SW2, similarly to the frequency converter 1 illustrated in FIG. 3. However, the frequency converter 1C does not include the switch SW1 illustrated in FIG. 3, and the midpoint of the primary winding of the transformer T2 is coupled to the ground. Note that, in the frequency converter 1C, the current control circuit that controls the direct current flowing via the transistors M1 to M4 is realized by the switch SW2.

When the frequency converter 1C operates in the reception mode, the switch SW2 couples the impedance circuit 11 to the power supply AVD. In this case, the current flows from the power supply AVD toward the ground via the impedance circuit 11 (Z1 and Z2), the transistors M1 to M4, and the transformer T2. For example, the transistors M1 to M4 are held in the active state. Therefore, the frequency converter 1C operates as an active-type frequency converter, in a reception and transmission mode in which a received RF signal is converted into the IF signal.

When the frequency converter 1C operates in the transmission mode, the switch SW2 couples the impedance circuit 11 to the ground. In this case, the direct current does not substantially flow via the transistors M1 to M4. For example, the double balanced mixer operates as a passive-type circuit.

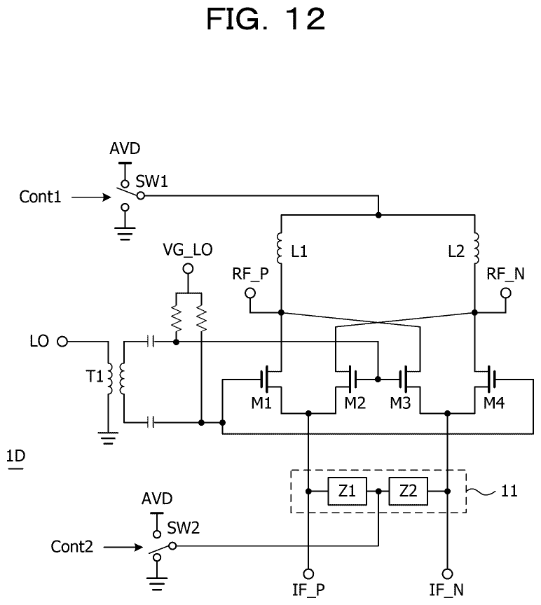

FIG. 12 illustrates an example of a frequency converter according to a third variation. A frequency converter 1D according to the third variation includes the double balanced mixer (transistors M1 to M4), the transformer T1, the impedance circuit 11, and the switches SW1 and SW2, similarly to the frequency converter 1 illustrated in FIG. 3. However, an RF signal processed by the frequency converter 1D is a differential signal. Therefore, a drain-side configuration of the double balanced mixer is different from that of the frequency converter 1 illustrated in FIG. 3.

In the frequency converter 1D, an RF_P terminal is coupled to the drains of the transistors M1 and M3, and an RF_N terminal is coupled to the drains of the transistors M2 and M4. Furthermore, the switch SW1 couples to the drains of the transistors M1 and M3 via an inductor L1 and couples to the drains of the transistors M2 and M4 via an inductor L2.

Control of the switches SW1 and SW2 is substantially the same as those in the frequency converter 1 illustrated in FIG. 3 and the frequency converter 1D illustrated in FIG. 12. For example, when the frequency converter 1D operates in the transmission mode, the switch SW1 couples the inductors L1 and L2 to the power supply AVD, and the switch SW2 couples the impedance circuit 11 to the ground. In this case, the current flows from the power supply AVD toward the ground via the inductors L1 and L2, the transistors M1 to M4, and the impedance circuit 11 (Z1 and Z2). Furthermore, when the frequency converter 1D operates in the reception mode, the switch SW1 couples the inductors L1 and L2 to the ground, and the switch SW2 couples the impedance circuit 11 to the power supply AVD. In this case, the current flows from the power supply AVD toward the ground via the impedance circuit 11 (Z1 and Z2), the transistors M1 to M4, and the inductors L1 and L2.

In this way, in both of the transmission mode and the reception mode, frequency conversion is performed while the transistors M1 to M4 are maintained to be in the active state. Furthermore, since the frequency converter 1D processes the differential RF signal, noise resistance in the communication device (for example, path between antenna and frequency converter) becomes stronger.

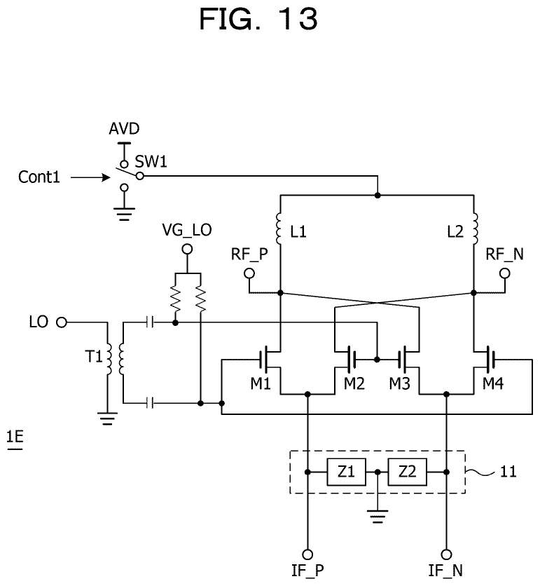

FIG. 13 illustrates an example of a frequency converter according to a fourth variation. A frequency converter 1E according to the fourth variation processes the differential RF signal, similarly to the frequency converter 1D illustrated in FIG. 12. However, the frequency converter 1E performs an active operation in the transmission mode and performs a passive operation in the reception mode. Therefore, a drain-side configuration of the double balanced mixer is the same as that of the frequency converter 1B illustrated in FIG. 10.

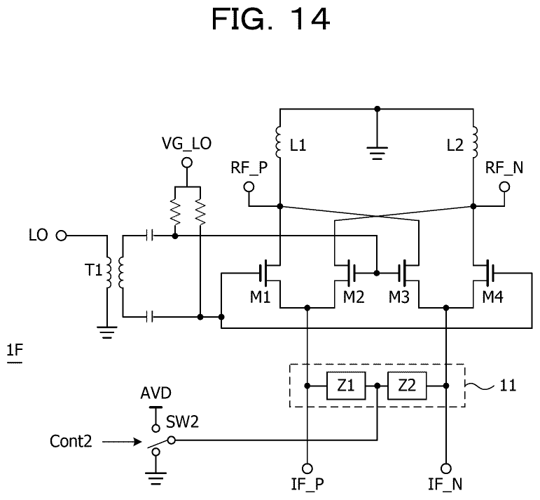

FIG. 14 illustrates an example of a frequency converter according to a fifth variation. A frequency converter 1F according to the fifth variation processes the differential RF signal, similarly to the frequency converter 1D illustrated in FIG. 12. However, the frequency converter 1F performs an active operation in the reception mode and performs a passive operation in the transmission mode. Therefore, a source-side configuration of the double balanced mixer is different from that of the frequency converter 1D. For example, the drains of the transistors M1 and M3 are coupled to the ground via the inductor L1, and the drains of the transistors M2 and M4 are coupled to the ground via the inductor L2.

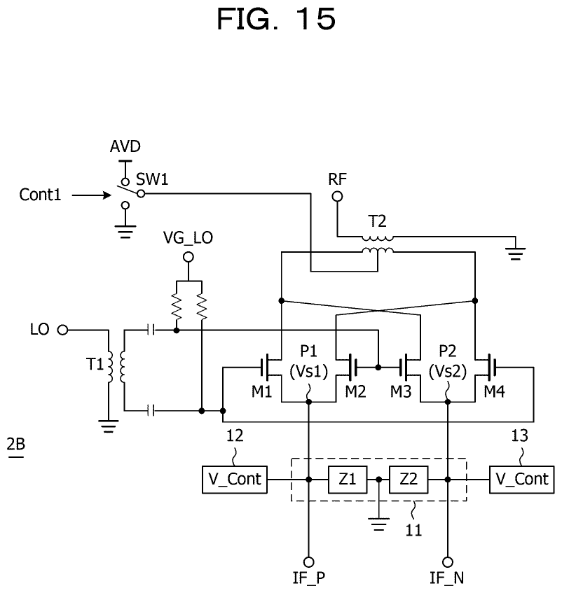

FIG. 15 illustrates an example of a frequency converter according to a sixth variation. A frequency converter 2B according to the sixth variation includes the voltage control circuits 12 and 13 and can suppress the LO leak power, similarly to the frequency converter 2 illustrated in FIG. 7. However, the frequency converter 2B performs the active operation in the transmission mode and performs the passive operation in the reception mode. Therefore, a drain-side configuration of the double balanced mixer is the same as that of the frequency converter 1B illustrated in FIG. 10.

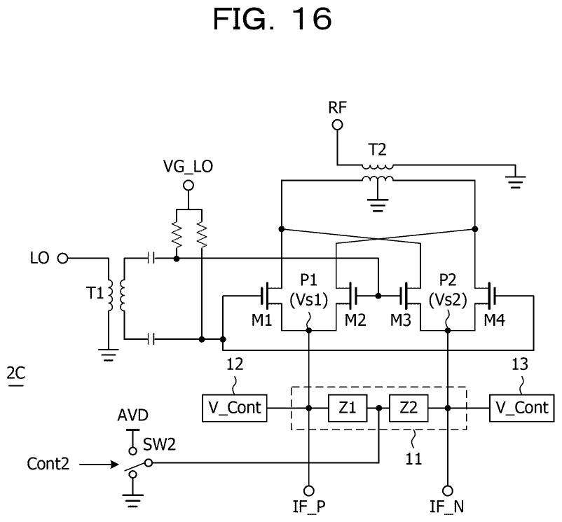

FIG. 16 illustrates an example of a frequency converter according to a seventh variation. A frequency converter 2C according to the seventh variation includes the voltage control circuits 12 and 13 and can suppress the LO leak power, similarly to the frequency converter 2 illustrated in FIG. 7. However, the frequency converter 2C performs the active operation in the reception mode and performs the passive operation in the transmission mode. Therefore, a drain-side configuration of the double balanced mixer is the same as that of the frequency converter 1C illustrated in FIG. 11.

### Application Example

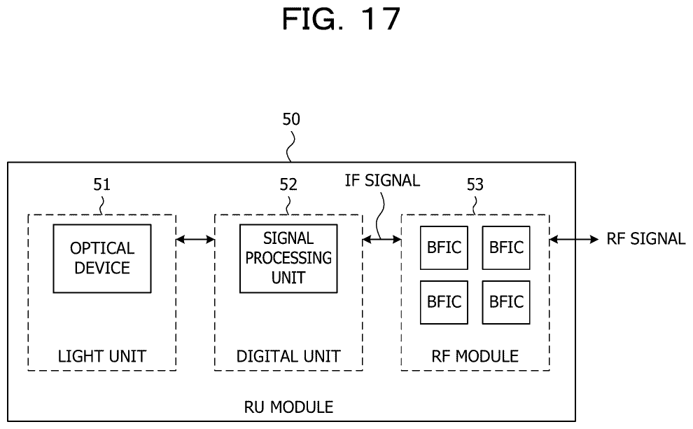

The frequency converter according to the embodiments is used, for example, in a base station device. The base station device includes, for example, an E2 node and a radio unit (RU) module. An RU module 50 includes, for example, a light unit 51, a digital unit 52, and an RF module 53, as illustrated in FIG. 17. The light unit 51 includes an optical device including an optical receiver and an optical transmitter. The optical receiver receives an optical signal transmitted from the E2 node. The optical transmitter transmits the optical signal to the E2 node. The digital unit 52 includes a signal processing unit. The signal processing unit generates a transmission signal to be transmitted from the base station to a terminal. This transmission signal is guided to the RF module 53 as an IF signal. Furthermore, the signal processing unit processes a signal received by the base station from the terminal. This signal is output from the RF module 53.

The RF module 53 includes a plurality of Beam Forming Integrated Circuits (BFIC). Each BFIC includes the frequency converter according to the embodiments. For example, the BFIC can up-convert the transmission signal generated by the digital unit 52 from an IF band to an RF band and output the transmission signal. Furthermore, the BFIC down-converts a signal received via an antenna from the RF band to the IF band and guides the signal to the digital unit 52.

Here, power saving of the RU module 50 is realized, by using the frequency converter according to the embodiments. Furthermore, a conversion efficiency of the frequency converter according to the embodiments is high. Therefore, a gain of an amplifier that amplifies the transmission signal and/or the reception signal can be reduced. For example, since a compact amplifier can obtain a signal with sufficient power, miniaturization of the RU module 50 can be realized. Moreover, since the spurious (LO leak power) is suppressed, quality of communication between the base station and the terminal is improved.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A frequency converter comprising:
a transistor configured to configure a double balanced mixer;
a load circuit provided to a drain side of the transistor;
a first terminal coupled to the load circuit;
an impedance circuit provided to a source side of the transistor;
a second terminal coupled to a source of the transistor;
a drive circuit configured to provide a local oscillator signal to a gate of the transistor; and
a current control circuit configured to control a current that flows from the load circuit toward the impedance circuit via the transistor or a current that flows from the impedance circuit toward the load circuit via the transistor.

2. The frequency converter according to claim 1, wherein
the current control circuit includes a first switch that couples the load circuit to a power supply or ground, according to a first control signal.

3. The frequency converter according to claim 1, wherein
the current control circuit includes a second switch that couples the impedance circuit to a power supply or ground, according to a second control signal.

4. The frequency converter according to claim 1, wherein
the current control circuit includes
a first switch that couples the load circuit to a power supply or ground, according to a first control signal, and
a second switch that couples the impedance circuit to the power supply or the ground, according to a second control signal,
when the first switch couples the load circuit to the power supply according to the first control signal, the second switch couples the impedance circuit to the ground according to the second control signal, and
when the first switch couples the load circuit to the ground according to the first control signal, the second switch couples the impedance circuit to the power supply according to the second control signal.

5. The frequency converter according to claim 4, wherein
the load circuit is a transformer,
the first switch couples to a midpoint of first winding of the transformer, and
the first terminal couples to second winding of the transformer.

6. The frequency converter according to claim 4, wherein
one terminal of the impedance circuit couples to the second switch,
another terminal of the impedance circuit couples to the source of the transistor and the second terminal, and
the impedance circuit has a predetermined resistance value with respect to a direct current and has a high impedance at an intermediate frequency.

7. The frequency converter according to claim 4, wherein
the double balanced mixer includes a first transistor, a second transistor, a third transistor, and a fourth transistor,
sources of the first transistor and the second transistor are coupled to each other,
sources of the third transistor and the fourth transistor are coupled to each other,
drains of the first transistor and the third transistor are coupled to each other, and
drains of the second transistor and the fourth transistor are coupled to each other.

8. The frequency converter according to claim 7, wherein
the load circuit is a transformer,
the drains of the first transistor and the third transistor are coupled to one end of first winding of the transformer,
the drains of the second transistor and the fourth transistor are coupled to another end of the first winding of the transformer,
the first switch couples to a midpoint of the first winding of the transformer, and
the first terminal couples to second winding of the transformer.

9. The frequency converter according to claim 7, wherein
the load circuit includes a first inductor and a second inductor,
the drains of the first transistor and the third transistor are coupled to the first switch via the first inductor, and
the drains of the second transistor and the fourth transistor are coupled to the first switch via the second inductor.

10. The frequency converter according to claim 1, further comprising:
a voltage control circuit configured to control a potential of the source of the transistor.

11. The frequency converter according to claim 10, wherein
the voltage control circuit controls the potential of the source of the transistor, so as to reduce a frequency component of the local oscillator signal output via the first terminal.
